(19) United States
(12) Patent Application Publication
(10) Pub. No.: US 2014/0110867 A1
(43) Pub. Date: Apr. 24, 2014

(54) Substrate and Method for Cutting the Substrate

(71) Applicant: Hsin-Hua Chen, Shenzhen City (CN)

(72) Inventor: Hsin-Hua Chen, Shenzhen City (CN)

(73) Assignee: Shenzhen China Star Optoelectronics Technology Co., Ltd., Shenzhen (CN)

(21) Appl. No.: 13/700,670

(22) PCT Filed: Nov. 1, 2012
(86) PCT No.: PCT/CN12/83921

§ 371 Date: Nov. 28, 2012

(30) Foreign Application Priority Data
Oct. 24, 2012 (CN) 201210410350.6

(51) Int. Cl. H01L 21/78; H01L 23/544

(52) U.S. Cl. CPC H01L 21/78; H01L 23/544
USPC 257/797; 438/462

(57) ABSTRACT

The present invention discloses a method for cutting a substrate. The method includes the steps of 1) creating a etching groove in the first surface of the first sheet and the third surface of the second sheet; 2) laminating the first and second sheets with the etching grooves aligned with each other; and 3) using a cutter to cut through the second surface of first sheet and the fourth surface of the second sheet along a preset set cutting line such that a crack extending vertically to the etching grooves so as to sever the first and second sheets. The present invention further discloses a substrate. By way of the foregoing, the taper and gradient along the cutting edge can be reduced.

The present invention relates to a technical field of liquid crystal display device, and more particularly w a substrate and at method for cutting the substrate.

### BACKGROUND OF THE INVENTION

Currently, the severance of the liquid substrate is made by cutting wheel. As shown in FIGS. 1 and 2, in which FIG. 1 is a working principle of a method for cutting a substrate; and FIG. 2 is a cross sectional view shown the substrate after severance. The substantial cutting procedures is 1) applying the cutting, wheel 100 toward a surface of the substrate 200 such that the surface is scored with a groove 300 which divides into a horizontal groove 300 and vertical groove 302. Then, pressure is applied on the opposite surface so as to extend the vertical groove 320 (dotted line in FIG. 1). Then the substrate is severed.

However, the existing cutting method inherits the potential problems.

1. When the pressure is applied on the opposite surface of the substrate 200, extension of the scored groove could be tilted or offset from its original direction.

2. The substrate 200 is configured with a thin-film transistor liquid crystal panel and a color filter substrate, once the taper of the thin-film transistor liquid crystal panel and the color filter substrate are different, a gradient could be formed therebetween.

3. The taper or gradient could fall within the specification, however, during the field inspection, the equipment could make an error in view of that. Accordingly, this will inevitably increase the workload of the personnel.

### SUMMARY OF THE INVENTION

The purpose of the present invention is to provide a method for cutting a substrate. The method can accelerate the cutting process and reduce the gradient created in the cutting edge. This will help to reduce the error of the inspecting equipment. This method will also reduce the workload of the personnel.

In order to resolve the issue encountered by the prior art, the present invention provides a technical solution by introducing a method for cutting a substrate which is configured with a first sheet having a first surface and a second surface opposite to the first surface, and a second sheet having a third surface and a fourth surface opposite to the third surface, characterized in that the method includes the steps of: creating a triangular etching groove on the first surface of the first sheet, and the third surface of the second sheet; laminating the first and second sheets such that the triangular etching grooves are matched together; using a cutter to cut through the second surface of first sheet and the fourth surface of the second sheet along a preset set cutting line such that a crack extending vertically to the etching grooves so as to sever the first and second sheets; and wherein the triangular etching groove is created through laser.

Characterized in that the cutting line is arranged within the span of the triangular etching groove.

Wherein the cutting lines on the second surface of the first sheet and the fourth surface of the second sheet are coplanar.

Characterized in that the first sheet is a thin-film transistor substrate.

Characterized in that the second sheet is a color filter substrate.

In order to resolve the issue encountered by the prior art, the present invention provides a technical solution by introducing a method for cutting a substrate which is configured with a first sheet having a first surface and a second surface opposite to the first surface, and a second sheet having a third surface and a fourth surface opposite to the third surface, characterized in that the method includes the steps of: creating a etching groove in the first surface of the first sheet and the third surface of the second sheet; laminating the first and second sheets with the etching grooves aligned with each other; and using a cutter to cut through the second surface of first sheet and the fourth surface of the second sheet along a preset set cutting line such that a crack extending vertically to the etching grooves so as to sever the first and second sheets.

Wherein the etching groove has a triangular cross section.

Characterized in that the etching groove is created by laser.

Characterized in that the cutting line is arranged within the span of the triangular etching groove.

Wherein the cutting lines on the second surface of the first sheet and the fourth surface of the second sheet are coplanar.

Wherein the cutter is a high performance cutting wheel.

Characterized in that the first sheet is a thin-film transistor substrate.

Characterized in that the second sheet is a color filter substrate.

In order to resolve the issue encountered by the prior art, the present invention provides a technical solution by introducing a substrate configured with a first sheet having a first surface and a second surface opposite to the first surface, and a second sheet having a third surface and a fourth surface opposite to the third surface, characterized in that a etching groove in the first surface of the first sheet and the third surface of the second sheet.

Characterized in that the first sheet is a thin-film transistor substrate and the second sheet is a color filter substrate.

By creating an etching groove on the first surface of the first sheet and a third surface of the second sheet, the cutting depth of the substrate is properly and vertically reduced. As a result, the cutting speed of the substrate can be accelerated. The gradient and taper on the cutting edge are also reduced so as to reduce the errors of the inspecting equipments. In addition, the workload of the personnel can also be lowered.

### BRIEF DESCRIPTION OF DRAWINGS

FIG. 1 is a working principle of a method for cutting a substrate;

FIG. 2 is a cross sectional view shown the substrate after severance;

FIG. 3 is a flow diagram of a method for cutting substrate made in accordance with the present invention; and

FIG. 4 is a configurational and structural view of the substrate made in accordance with the present invention.

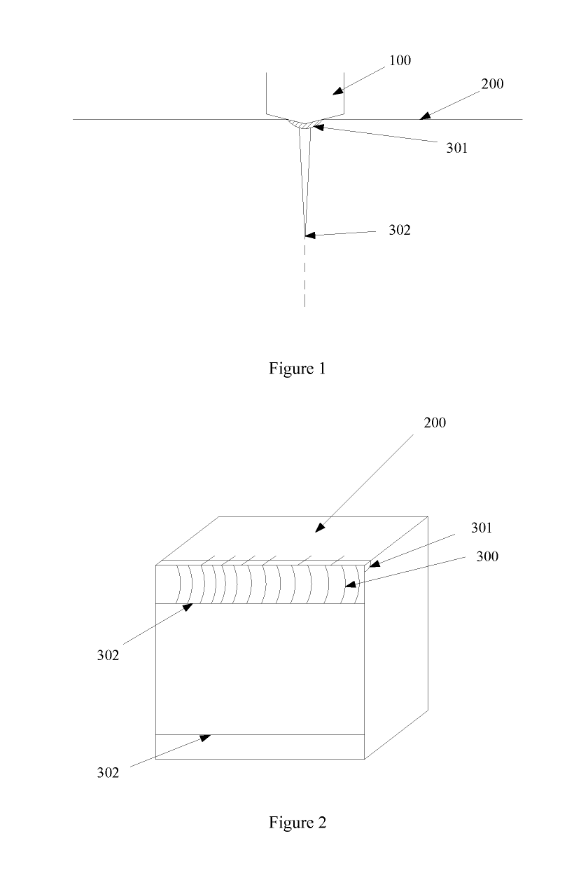

### DETAILED DESCRIPTION OF PREFERRED EMBODIMENT

Detailed description will he given to the embodiments along with the accompanied drawings.

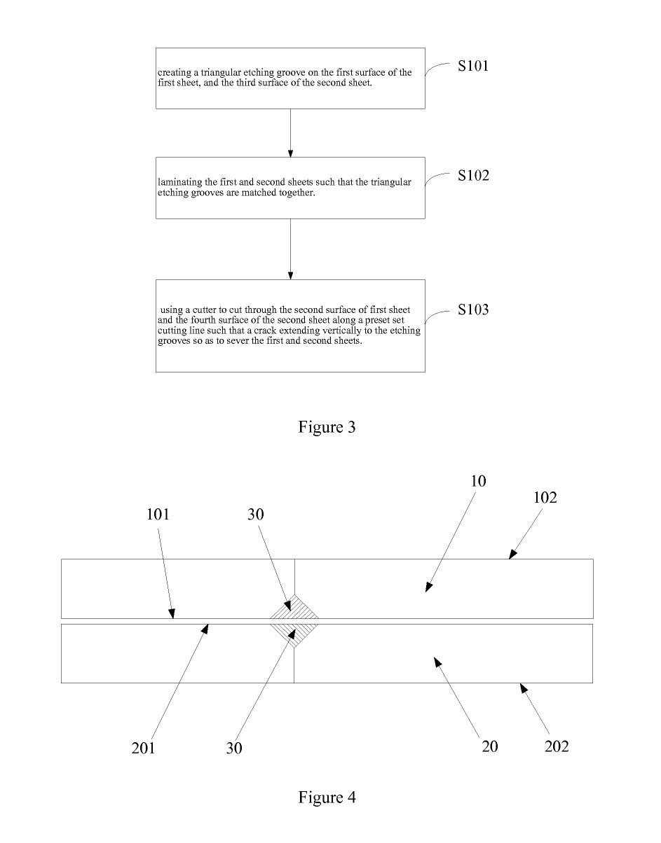

Referring to FIG. 3, which is a flow diagram of a method for cutting substrate made in accordance with the present invention. The substrate is configured with a first sheet having a first surface and a second surface opposite to the first surface, and a second sheet having a third surface and a fourth surface opposite to the third surface. The first sheet is a thin-film transistor liquid crystal display, and the second sheet is a color filter substrate. Of course, the first sheet can he a color filter sheet, and the second sheet can he the thin-film transistor liquid crystal display. No limitation should be imposed thereon. The method of cutting the substrate includes the steps of following.

Step S101: creating a triangular etching groove on the first surface of the first sheet, and the third surface of the second sheet.

In the current embodiment, it is preferable to have the cross section of the etching groove in the shape of a triangular. Normally, after the substrate is severed, the cutting edges have to he further processed to smooth out. When the etching groove has the triangular shape, the cutting, edge will he formed with a chamfered angle, and this will easy out the grinding work of the cutting edge. Of course, the etching edge can be of other suitable shape as long as it can accelerate the cutting speed, reducing the taper and gradient thereof. No limitation should be set up here.

Further, in the current embodiment, the etching groove is formed by laser, while it should be noted that the present invention is not limited thereto.

Step S102: laminating the first and second sheets such that the triangular etching grooves are matched together.

In this step, the first surface of the first sheet and the third surface of the second sheet are laminated with the etching grooves thereon aligned with each other. As a result, once the substrate is severed, the cutting edge of the first and second sheets are consistent with each other.

Step S103: using a cutter to cut through the second surface of first sheet and the fourth surface of the second sheet along a preset set cutting line such that a crack extending vertically to the etching grooves so as to sever the first and second sheets.

In the current embodiment, a high performance of cutting wheel is utilized. The peripheral of the cutting wheel is formed with an angle or even cutting tooth so as to create the cutting effect. In addition, in order to reduce the taper and the gradient created along the cutting edge, a cutting line is set to in align with the etching groove, i.e. the cutting line is set within the span of the etching grooves created in the first surface of the first sheet and the third surface of the second sheet. In addition, the cutting line on in the first surface of the first sheet and the third surface of the second sheet are coplanar.

Taking a triangular etching groove as an example, a vertical crack created by the cutting wheel extends to an apex of the triangular etching groove as it is the shortest distance to the etching groove. This will be the fastest way to cut the substrate off. In addition, this will also benefit a modest taper and gradient along the cutting edge.

By creating an etching groove on the first surface of the first sheet and a third surface of the second sheet, the cutting depth of the substrate is properly and vertically reduced. As a result, the cutting speed of the substrate can he accelerated. The gradient and taper on the cutting edge are also reduced so as to reduce the errors of the inspecting equipments. In addition, the workload of the personnel can also be lowered.

Referring to FIG. 4, which a configurational and structural view of the substrate made in accordance with the present invention. The substrate includes a first sheet 10 and a second sheet 20.

The first sheet 10 includes a first surface 101 and a second surface 102 opposite to the first surface 101. The second sheet 20 includes a third surface 201 and a fourth surface 202 opposite to the third surface 201. In the current embodiment, the first sheet 10 is a thin-film transistor liquid crystal display, and the second sheet is a color filter substrate. It should be noted that when the substrate is severed, the first surface 101 of the first sheet 10 and the third surface 201 of the second sheet 20 are laminated together, however, in the FIG. 4, the first sheet 10 and the second sheet 20 are separated for readily illustration.

An etching groove 30 is created on the first surface 101 of the first sheet 10, and the third surface 201 of the second sheet 20. The number of the etching groove 30 can be multiple and each of the etching grooves 30 is spaced from one another. In the current embodiment, the cross sectional view of the etching groove 30 is a triangular shape. Of course, any suitable shape can be adopted as long as the cutting speed can be accelerated, while the taper and gradient along the cuffing edge can be reduced. In addition, the present invention should not be limited to such an embodiment. Further, the etching groove 30 is created by a laser beam. Again, no limitation should be imposed.

By creating an etching groove on the first surface of the first sheet and a third surface of the second sheet, the cutting depth of the substrate is properly and vertically reduced. As a result, the cutting speed of the substrate can be accelerated. The gradient and taper on the cutting edge are also reduced so as to reduce the errors of the inspecting equipments. In addition, the workload of the personnel can also be lowered.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

1. A method for cutting a substrate which is configured with a first sheet having a first surface and a second surface opposite to the first surface, and a second sheet having a third surface and a fourth surface opposite to the third surface, characterized in that the method includes the steps of:
creating a triangular etching groove on the first surface of the first sheet, and the third surface of the second sheet;
laminating the first and second sheets such that the triangular etching grooves are matched together;
using a cutter to cut through the second surface of first sheet and the fourth surface of the second sheet along a preset set cutting line such that a crack extending vertically to the etching grooves so as to sever the first and second sheets; and
wherein the triangular etching groove is created through laser.

2. The method as recited in claim 1, characterized in that the cutting line is arranged within the span of the triangular etching groove.

3. The method as recited in claim 2, wherein the cutting lines on the second surface of the first sheet and the fourth surface of the second sheet are coplanar.

4. The method as recited in claim 1, characterized in that the first sheet is a thin-film transistor substrate.

5. The method as recited in claim 4, characterized in that the second sheet is a color filter substrate.

6. A method for cutting a substrate which is configured with a first sheet having a first surface and a second surface opposite to the first surface, and a second sheet having a third surface and a fourth surface opposite to the third surface, characterized in that the method includes the steps of:
creating an etching groove in the first surface of the first sheet and the third surface of the second sheet;
laminating the first and second sheets with the etching grooves aligned with each other; and using a cutter to cut through the second surface of first sheet and the fourth surface of the second sheet along a preset set cutting line such that a crack extending vertically to the etching grooves so as to sever the first and second sheets.

7. The method as recited in claim 6, wherein the etching groove has a triangular cross section.

8. The method as recited in claim 7, characterized in that the etching groove is created by laser.

9. The method as recited in claim 6, characterized in that the cutting line is arranged within the span of the triangular etching groove.

10. The method as recited in claim 9, wherein the cutting lines on the second surface of the first sheet and the fourth surface of the second sheet are coplanar.

11. The method as recited in claim 6, wherein the cutter is a high performance cutting wheel.

12. The method as recited in claim 1, characterized in that the first sheet is a thin-film transistor substrate.

13. The method as recited in claim 12, characterized in that the second sheet is a color filter substrate.

14. A substrate configured with a first sheet having a first surface and a second surface opposite to the first surface, and a second sheet haying a third surface and a fourth surface opposite to the third surface, characterized in that a etching groove in the first surface of the first sheet and the third surface of the second sheet

15. The substrate as recited in claim 14, characterized in that the first sheet is a thin-film transistor substrate and the second sheet is a color filter substrate.
